(19) United States
(12) Patent Application Publication
(10) Pub. No.: US 2020/0411688 A1
(43) Pub. Date: Dec. 31, 2020

(54) SEMICONDUCTOR DEVICE WITH ANTI-HOT ELECTRON EFFECT CAPABILITY

(71) Applicant: NANYA TECHNOLOGY CORPORATION, NEW TAIPEI CITY (TW)

(72) Inventor: CHUN-CHENG LIAO, NEW TAIPEI CITY (TW)

(21) Appl. No.: 16/455,008

(22) Filed: Jun. 27, 2019

(51) Int. Cl. H01L 29/78; H01L 29/06; H01L 29/66; H01L 21/266

(52) U.S. Cl. CPC H01L 29/7833; H01L 21/266; H01L 29/6656; H01L 29/0649

(57) ABSTRACT

A semiconductor device includes a substrate, a control structure positioned in the substrate, a plurality of first spacers positioned on two sidewalls of the control structure, a plurality of second spacers positioned on sidewalls of the plurality of first spacers, and a first doped region positioned in the substrate. The first doped region includes a lightly-doped area, a medium-doped area, and a heavily-doped area. The lightly-doped area of the first doped region abuts against one edge of the control structure. The medium-doped area of the first doped region abuts against the lightly-doped area of the first doped region. The heavily-doped area of the first doped region is enclosed by the medium-doped area of the first doped region.

### TECHNICAL FIELD

The present disclosure relates to a semiconductor device and a fabrication method for the semiconductor device, and more particularly, to a semiconductor device with anti-hot electron effect capability and a fabrication method for the semiconductor device with anti-hot electron effect capability.

### DISCUSSION OF THE BACKGROUND

Semiconductor devices are used in a variety of electronic applications, such as personal computers, cell phones, digital cameras, and other electronic equipment. The dimension of semiconductor devices is continuously being scaled down to meet the increasing demand of computing ability. However, a variety of issues such as hot electron effect arise during the scaling down process. Therefore, challenges remain in achieving improved quality, yield, and reliability.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate, a control structure positioned in the substrate, a plurality of first spacers positioned on two sidewalls of the control structure, a plurality of second spacers positioned on sidewalls of the plurality of first spacers, and a first doped region positioned in the substrate. The first doped region comprises a lightly-doped area, a medium-doped area, and a heavily-doped area. The lightly-doped area of the first doped region abuts against one edge of the control structure. The medium-doped area of the first doped region abuts against the lightly-doped area of the first doped region. The heavily-doped area of the first doped region is enclosed by the medium-doped area of the first doped region.

Another aspect of the present disclosure provides a semiconductor device including a substrate, a control structure positioned in the substrate, a plurality of first spacers positioned on two sidewalls of the control structure, a plurality of second spacers positioned on sidewalls of the plurality of first spacers, and a plurality of first doped regions positioned in the substrate. Each of the plurality of first doped regions comprises a lightly-doped area, a medium-doped area, and a heavily-doped area. The lightly-doped areas of the plurality of first doped regions alternately abut against one edge of the control structure. The medium-doped areas of the plurality of first doped regions correspondingly respectively abut against the lightly-doped areas of the plurality of first doped regions. The heavily-doped areas of the plurality of first doped regions are correspondingly respectively enclosed by the medium-doped areas of the plurality of first doped regions.

Another aspect of the present disclosure provides a method for fabrication of a semiconductor device including providing a substrate, forming a control structure above the substrate, forming a first lightly-doped area and a second lightly-doped area in the substrate, forming a plurality of first spacers attached to two sidewalls of the control structure, forming a first medium-doped area and a second medium-doped area in the substrate, forming a plurality of second spacers attached to two sidewalls of the plurality of first spacers, and forming a first heavily-doped area and a second heavily-doped area in the substrate. The first lightly-doped area is separated from the second lightly-doped area. The first medium-doped area is separated from the second medium-doped area. The first heavily-doped area is separated from the second heavily-doped area.

Due to the design of the semiconductor device, it is possible to mitigate the hot electron effect in the semiconductor device and reduce the complexity and the cost of fabrication of the semiconductor device.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 and FIGS. 5 to 9 illustrate, in schematic cross-sectional diagrams, several semiconductor devices in accordance with some embodiments of the present disclosure;

FIGS. 2 to 4 and FIG. 10 illustrate, in schematic top-view diagrams, several semiconductor devices in accordance with some embodiments of the present disclosure;

FIG. 11 illustrates, in flowchart diagram form, a method for fabricating a semiconductor device in accordance with an embodiment of the present disclosure; and

FIGS. 12 to 20 illustrate, in schematic cross-sectional diagram, a flow of fabricating a semiconductor device in accordance with an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Note that, in the description of the present disclosure, above (or up) corresponds to the direction of the arrow of the direction Z, and below (or down) corresponds to the opposite direction of the arrow of the direction Z.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

In the present disclosure, a semiconductor device and fabrication method for the semiconductor device are depicted.

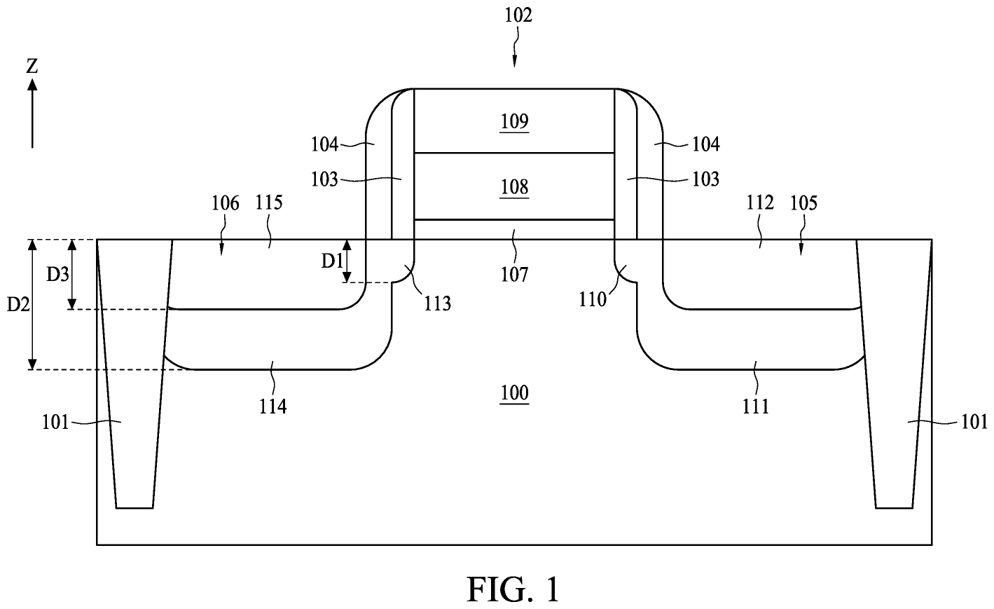

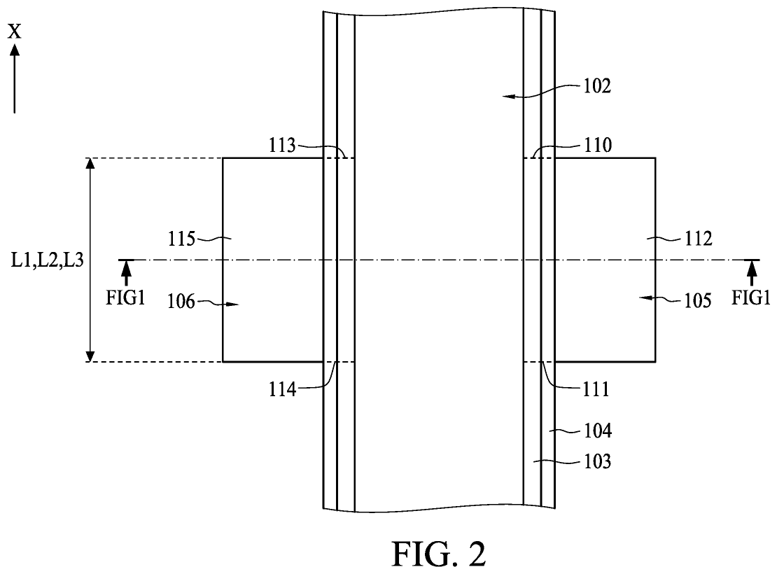

With reference to FIG. 1 and FIG. 2, a semiconductor device includes, for example, a substrate 100, a plurality of isolation structures 101, a control structure 102, a plurality of first spacers 103, a plurality of second spacers 104, a first doped region 105, and a second doped region 106.

With reference to FIG. 1 and FIG. 2, the substrate 100 is formed of, for example, silicon, doped silicon, silicon germanium, silicon on insulator, silicon on sapphire, silicon germanium on insulator, silicon carbide, germanium, gallium arsenide, gallium phosphide, gallium arsenide phosphide, indium phosphide, indium gallium phosphide, or any other IV-IV, III-V or II-VI semiconductor material. In the embodiment depicted, the substrate 100 is formed of doped silicon, which is doped with boron. Alternatively, in another embodiment depicted, the substrate 100 is formed of silicon on insulator and the silicon on insulator substrate 100 may mitigate the parasitic capacitance issue and reduce leakage currents of the semiconductor device.

With reference to FIG. 1, the plurality of isolation structures 101 (not shown in FIG. 2) may be disposed in the substrate 100 and are separated from each other. The plurality of isolation structures 101 define an active region of the semiconductor device. The plurality of isolation structures 101 are formed of, for example, an insulating material such as silicon oxide, silicon nitride, silicon oxynitride, silicon nitride oxide, fluoride-doped silicate, or the like. In the embodiments depicted, the plurality of isolation structures 101 are formed of silicon oxide.

With reference to FIG. 1 and FIG. 2, the control structure 102 may be disposed above the substrate 100 and may be disposed in the active region defined by the plurality of isolation structures 101. In the embodiment depicted, the control structure 102 is disposed on the substrate 100. The control structure 102 may include an insulating layer 107, a middle layer 108, and a top layer 109. The insulating layer 107 may be disposed above the substrate 100. In the embodiment depicted, the insulating layer 107 is disposed on the substrate 100. The insulating layer 107 is formed of, for example, silicon oxide, silicon oxynitride, silicon nitride oxide, silicon nitride, or the like. In the embodiment depicted, the insulating layer 107 is formed of silicon oxide. The middle layer 108 may be disposed above the insulating layer 107. In the embodiment depicted, the middle layer 108 is disposed on the insulating layer 107 and is opposite to the substrate 100. The middle layer 108 is formed of, for example, polysilicon. In the embodiment depicted, the middle layer 108 is formed of polysilicon doped with phosphorus. The top layer 109 may be disposed above the middle layer 108. In the embodiment depicted, the top layer 109 is disposed on the middle layer 108 and is opposite to the insulating layer 107 with the middle layer 108 interposed therebetween. The top layer 109 is formed of, for example, a metal silicide such as nickel silicide, platinum silicide, titanium silicide, molybdenum silicide, cobalt silicide, tantalum silicide, tungsten silicide, or the like. In the embodiment depicted, the top layer 109 is formed of tungsten silicide.

Note that, in the present disclosure, silicon oxynitride refers to a substance which contains silicon, nitrogen, and oxygen and in which a proportion of oxygen is greater than that of nitrogen. Silicon nitride oxide refers to a substance which contains silicon, oxygen, and nitrogen and in which a proportion of nitrogen is greater than that of oxygen.

Alternatively, in another embodiment depicted, the insulating layer 107 may be formed of barium strontium titanate, lead zirconium titanate, titanium oxide, aluminum oxide, hafnium oxide, yttrium oxide, zirconium oxide, or the like. The middle layer 108 may be formed of titanium nitride. The top layer 109 may be formed of tantalum nitride.

With reference to FIG. 1 and FIG. 2, the plurality of first spacers 103 may be disposed above the substrate 100. The plurality of first spacers 103 may respectively attach to two sidewalls of the control structure 102. In the embodiment depicted, the plurality of first spacers 103 are disposed on the substrate 100. Bottom surfaces of the plurality of first spacers 103 respectively contact the substrate 100. The plurality of first spacers 103 are separated from each other and respectively attach to the two sidewalls of the control structure 102. The plurality of first spacers 103 are formed of, for example, silicon oxide, silicon nitride, polysilicon, or the like. In the embodiment depicted, the plurality of first spacers 103 are formed of silicon nitride.

With reference to FIG. 1 and FIG. 2, the plurality of second spacers 104 may be disposed above the substrate 100. The plurality of second spacers 104 may respectively attach to sidewalls of the plurality of first spacers 103. In the embodiment depicted, the plurality of second spacers 104 are disposed on the substrate 100. Bottom surfaces of the plurality of second spacers 104 respectively contact the substrate 100. The plurality of second spacers 104 are separated from each other. One of the plurality of second spacers 104 attaches to the sidewall of one of the plurality of first spacers 103. Another of the plurality of second spacers 104 attaches to the sidewall of another of the plurality of first spacers 103. The plurality of second spacers 104 are formed of, for example, silicon oxide, silicon nitride, or the like. In the embodiment depicted, the plurality of second spacers 104 are formed of silicon oxide.

With reference to FIG. 1 and FIG. 2, the first doped region 105 may be disposed in the substrate 100. The first doped region 105 abuts against one edge of the control structure 102. Part of the first doped region 105 is opposite to the one of the plurality of first spacers 103 and the one of the plurality of second spacers 104. In the embodiments depicted, the first doped region 105 includes a lightly-doped area 110, a medium-doped area 111, and a heavily-doped area 112.

With reference to FIG. 1 and FIG. 2, the lightly-doped area 110 of the first doped region 105 is disposed in the substrate 100 and abuts against the one edge of the control structure 102. Specifically, the lightly-doped area 110 of the first doped region 105 abuts against one edge of the insulating layer 107 of the control structure 102. Note that the lightly-doped area 110 of the first doped region 105 is not below the control structure 102. The lightly-doped area 110 of the first doped region 105 is below the one of the plurality of first spacers 103. A top surface of the lightly-doped area 110 of the first doped region 105 contacts the bottom surface of the one of the plurality of first spacers 103. Alternatively, in another embodiment depicted, part of the lightly-doped area 110 of the first doped region 105 may be below the control structure 102.

With reference to FIG. 1 and FIG. 2, the medium-doped area 111 of the first doped region 105 is disposed in the substrate 100 and abuts against the lightly-doped area 110 of the first doped region 105. Part of the medium-doped area 111 of the first doped region 105 is below the one of the plurality of second spacers 104. A top surface of the medium-doped area 111 of the first doped region 105 contacts the bottom surface of the one of the plurality of second spacers 104.

With reference to FIG. 1 and FIG. 2, the heavily-doped area 112 of the first doped region 105 is disposed in the substrate 100 and is enclosed by the medium-doped area 111 of the first doped region 105. The heavily-doped area 112 of the first doped region 105 is opposite to the lightly-doped area 110 of the first doped region 105 with the medium-doped area 111 of the first doped region 105 interposed therebetween. Note that the heavily-doped area 112 of the first doped region 105 is not below the control structure 102, the one of the plurality of first spacers 103, or the one of the plurality of second spacers 104.

With reference to FIG. 1, the lightly-doped area 110 of the first doped region 105 has a depth D1 (parallel to the direction Z). The medium-doped area 111 of the first doped region 105 has a depth D2 (parallel to the direction Z). The heavily-doped area 112 of the first doped region 105 has a depth D3 (parallel to the direction Z). In the embodiment depicted, the depth D1 of the lightly-doped area 110 of the first doped region 105 is less than the depth D2 of the medium-doped area 111 of the first doped region 105 and the depth D3 of the heavily-doped area 112 of the first doped region 105. The depth D3 of the heavily-doped area 112 of the first doped region 105 is less than the depth D2 of the medium-doped area 111 of the first doped region 105.

With reference to FIG. 2, the lightly-doped area 110 of the first doped region 105 has a length L1 (parallel to the direction X), the medium-doped area 111 of the first doped region 105 has a length L2 (parallel to the direction X), and the heavily-doped area 112 of the first doped region 105 has a length L3 (parallel to the direction X). In the embodiment depicted, the length L1 of the lightly-doped area 110 of the first doped region 105 is equal to the length L2 of the medium-doped area 111 of the first doped region 105 and the length L3 of the heavily-doped area 112 of the first doped region 105.

The lightly-doped area 110 of the first doped region 105 is doped with a dopant that is different from the dopant of the substrate 100. The lightly-doped area 110 of the first doped region 105 has a dopant concentration C1. The medium-doped area 111 of the first doped region 105 is doped with a dopant that is the same as the dopant of the lightly-doped area 110 of the first doped region 105 and has a dopant concentration C2. The heavily-doped area 112 of the first doped region 105 is doped with a dopant that is the same as the dopant of the medium-doped area 111 of the first doped region 105 and has a dopant concentration C3. The dopant concentration C3 of the heavily-doped area 112 of the first doped region 105 may be greater than the dopant concentration C2 of the medium-doped area 111 of the first doped region 105 and the dopant concentration C1 of the lightly-doped area 110 of the first doped region 105. The dopant concentration C2 of the medium-doped area 111 of the first doped region 105 may be greater than the dopant concentration C1 of the lightly-doped area 110 of the first doped region 105.

Specifically, in the embodiment depicted, the lightly-doped area 110 of the first doped region 105 is doped with phosphorus and the dopant concentration of the lightly-doped area 110 of the first doped region 105 is about 1E14 atoms/cm³ to about 1E16 atoms/cm³. The dopant concentration C2 of the medium-doped area 111 of the first doped region 105 is about 1E15 atoms/cm³ to about 1E17 atoms/cm³. The dopant concentration C3 of the heavily-doped area 112 of the first doped region 105 is about 1E17 atoms/cm³ to about 1E19 atoms/cm³. Alternatively, in another embodiment depicted, the medium-doped area 111 of the first doped region 105 is doped with a dopant that is different from the dopant of the substrate 100 and is different from the dopant of the lightly-doped area 110 of the first doped region 105. The heavily-doped area 112 of the first doped region 105 is doped with a dopant that is different from the dopant of the substrate 100 and is different from the dopant of the medium-doped area 111 of the first doped region 105.

With reference to FIG. 1 and FIG. 2, the second doped region 106 may be disposed in the substrate 100 and may be symmetrical to the first doped region 105. The second doped region 106 abuts against the other edge of the control structure 102. Part of the second region 106 is opposite to the other of the plurality of first spacers 103 and the other of the plurality of second spacers 104. In the embodiment depicted, the second doped region 106 includes a lightly-doped area 113, a medium-doped area 114, and a heavily-doped area 115.

With reference to FIG. 1 and FIG. 2, the lightly-doped area 113 of the second doped region 106 is disposed in the substrate 100 and abuts against the other edge of the control structure 100. In other words, the lightly-doped area 113 of the second doped region 106 is opposite to the lightly-doped area 110 of the first doped region 105. Specifically, the lightly-doped area 113 of the second doped region 106 abuts against the other edge of the insulating layer 107 of the control structure 102. Note that the lightly-doped area 113 of the second doped region 106 is not below the control structure 102. The lightly-doped area 113 of the second doped region 106 is below another of the plurality of first spacers 103. A top surface of the lightly-doped area 113 of the second doped region 106 contacts the bottom surface of the other of the plurality of first spacers 103. Alternatively, in another embodiment depicted, part of the lightly-doped area 113 of the second doped region 106 may be below the control structure 102.

With reference to FIG. 1 and FIG. 2, the medium-doped area 114 of the second doped region 106 is disposed in the substrate 100 and abuts against the lightly-doped area 113 of the second doped region 106. The medium-doped area 114 of the second doped region 106 is opposite to the medium-doped area 111 of the first doped region 105. Part of the medium-doped area 114 of the second doped region 106 is below the other of the plurality of second spacers 104. A top surface of the medium-doped area 114 of the second doped region 106 contacts the bottom surface of another of the plurality of second spacers 104.

With reference to FIG. 1 and FIG. 2, the heavily-doped area 115 of the second doped region 106 is disposed in the substrate 100 and is enclosed by the medium-doped area 114 of the second doped region 106. The heavily-doped area 115 of the second doped region 106 is opposite to the lightly-doped area 113 of the second doped region 106 with the medium-doped area 114 of the second doped region 106 interposed therebetween. The heavily-doped area 115 of the second doped region 106 is opposite to the heavily-doped area 112 of the first doped region 105. Note that the heavily-doped area 115 of the second doped region 106 is not below the control structure 102, the other of the plurality of first spacers 103, or the other of the plurality of second spacers 104.

With reference to FIG. 1, the lightly-doped area 113 of the second doped region 106 has a depth equal to the depth D1 of the lightly-doped area 110 of the first doped region 105. The medium-doped area 114 of the second doped region 106 has a depth equal to a depth of the medium-doped area 111 of the first doped region 105. The heavily-doped area 115 of the second doped region 106 has a depth equal to a depth of the heavily-doped area 112 of the first doped region 105.

With reference to FIG. 2, the lightly-doped area 113 of the second doped region 106 has a length equal to the length L1 of the lightly-doped area 110 of the first doped region 105. The medium-doped area 114 of the second doped region 106 has a length equal to the length L2 of the medium-doped area 111 of the first doped region 105. The heavily-doped area 115 of the second doped region 106 has a length equal to the length L3 of the heavily-doped area 112 of the first doped region 105.

The lightly-doped area 113 of the second doped region 106 is doped with a dopant that is different from the dopant of the substrate 100. The lightly-doped area 113 of the second doped region 106 has a dopant concentration equal to the dopant concentration C1 of the lightly-doped area 110 of the first doped region 105. The medium-doped area 114 of the second doped region 106 is doped with a dopant that is different from the dopant of the substrate 100. The medium-doped area 114 of the second doped region 106 has a dopant concentration equal to the dopant concentration C2 of the medium-doped area 111 of the first doped region 105. The heavily-doped area 115 of the second doped region 106 is doped with a dopant that is different from the dopant of the substrate 100. The heavily-doped area 115 of the second doped region 106 has a dopant concentration equal to the dopant concentration C3 of the heavily-doped area 112 of the first doped region 105.

In the present disclosure, the lightly-doped area 113 of the second doped region 106, the lightly-doped area 110 of the first doped region 105, the medium-doped area 114 of the second doped region 106, and the medium-doped area 111 of the first doped region 105 are adjacent to the control structure 102 and may attract hot electrons induced by the high electric field created by the scaled down semiconductor device. Therefore, the hot electron effect may be mitigated.

The plurality of first spacers 103 and the plurality of second spacers 104 may help to increase the vertical electric field above the lightly-doped area 113 of the second doped region 106, the lightly-doped area 110 of the first doped region 105, the medium-doped area 114 of the second doped region 106, and the medium-doped area 111 of the first doped region 105 to increase the anti-hot electron capability of the semiconductor device.

With presence of the plurality of second spacers 104, a thickness of the plurality of first spacers 103 may be minimized, thereby reducing overlap capacitance formed between the first doped region 105 and the control structure 102 or the second doped region 106 and the control structure 102.

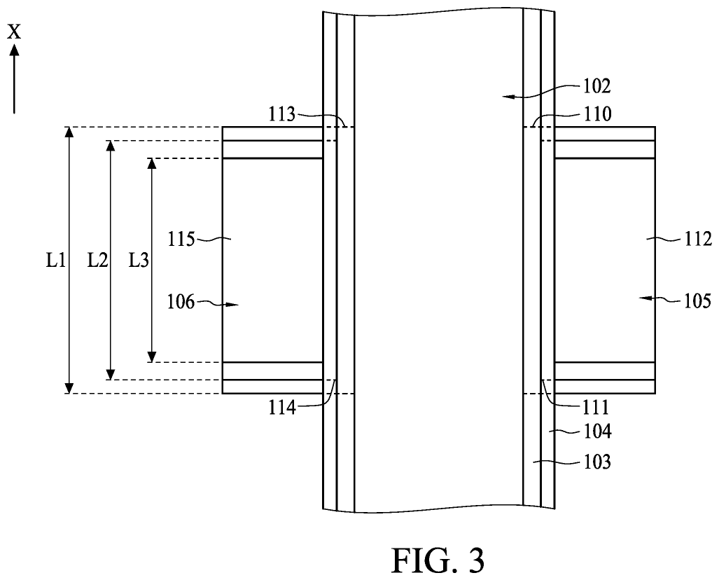

Alternatively, in another embodiment depicted, with reference to FIG. 3, the length L1 of the lightly-doped area 110 of the first doped region 105 is greater than the length L2 of the medium-doped area 111 of the first doped region 105 and the length L3 of the heavily-doped area 112 of the first doped region 105. The length L2 of the medium-doped area 111 of the first doped region 105 is greater than the length L3 of the heavily-doped area 112 of the first doped region 105. The greater length of the lightly-doped area 110 of the first doped region 105 and the medium-doped area 111 of the first doped region 105 may increase the capability of preventing hot electrons from being injected into the insulating layer 107 of the control structure 102.

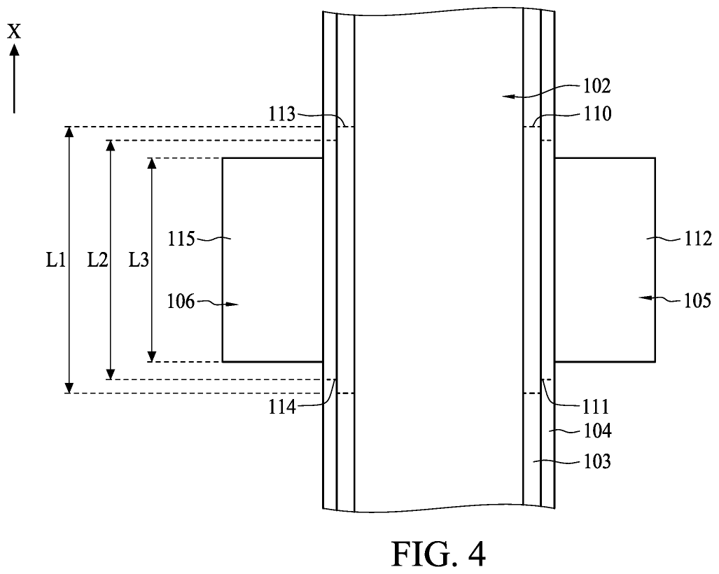

Alternatively, in another embodiment depicted, with reference to FIG. 4, a portion of the lightly-doped area 110 of the first doped region 105, i.e., the portion which is below the one of the plurality of first spacers 103, has a length L1. The remaining portion of the lightly-doped area 110 of the first doped region 105 has a length L3. The length L1 of the portion of the lightly-doped area 110 of the first doped region 105 is greater than the length L3 of the remaining portion of the lightly-doped area 110 of the first doped region 105. That is to say, from a top view, the lightly-doped area 110 of the first doped region 105 forms a T-shape pattern. A portion of the medium-doped area 111 of the first doped region 105, i.e., the portion which is below the one of the plurality of second spacers 104, has a length L2. The remaining portion of the medium-doped area 111 of the first doped region 105 has a length equal to the length L3 of the remaining portion of the lightly-doped area 110 of the first doped region 105. The length L2 of the portion of the medium-doped area 111 of the first doped region 105 is greater than the length L3 of the remaining portion of the lightly-doped area 110 of the first doped region 105. That is to say, from a top view, the medium-doped area 111 of the first doped region 105 forms a T-shape pattern. The heavily-doped area 112 of the first doped region 105 has a length equal to the length L3 of the remaining portion of the lightly-doped area 110 of the first doped region 105. Compared to the embodiment depicted in FIG. 3, the T-shaped lightly-doped area 110 of the first doped region 105 and the T-shaped medium-doped area 111 of the first doped region 105 indicate the smaller space in the substrate 100. The resistance is proportional to the space of the first doped region 105 in the substrate 100. Therefore, the semiconductor device depicted in FIG. 4 may exhibit lower power dissipation due to the smaller space of the first doped region 105 in the substrate 100.

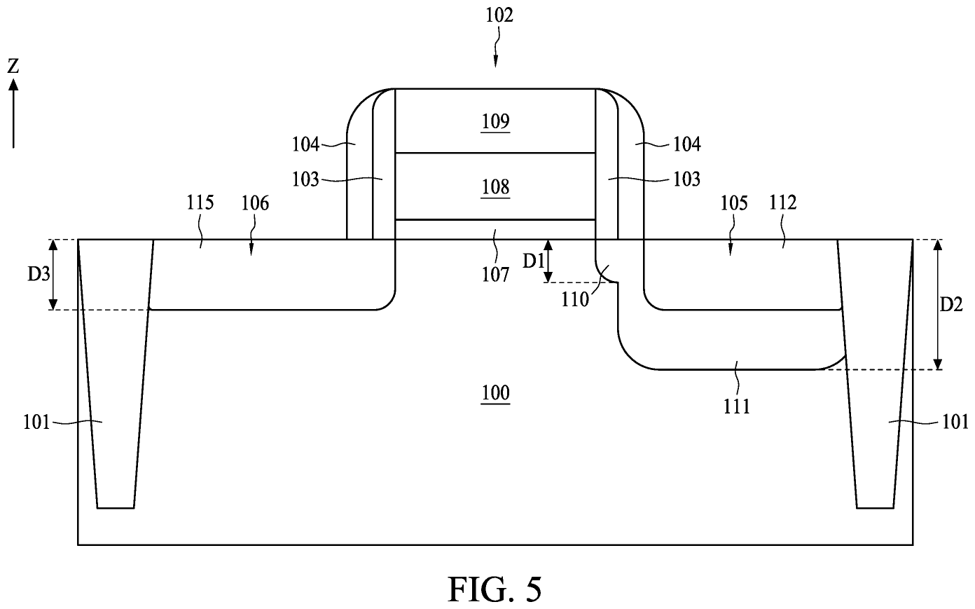

Alternatively, in another embodiment depicted, with reference to FIG. 5, the first doped region 105 and the second doped region 106 are asymmetrical. Specifically, the second doped region 106 includes only a heavily-doped area 115. Part of the heavily-doped area 115 of the second doped region 106 is below the other of the plurality of first spacers 103 and the other of the plurality of second spacers 104. A top surface of the heavily-doped area 115 of the second doped region 106 contacts the bottom surfaces of the other of the plurality of first spacers 103 and the other of the plurality of second spacers 104.

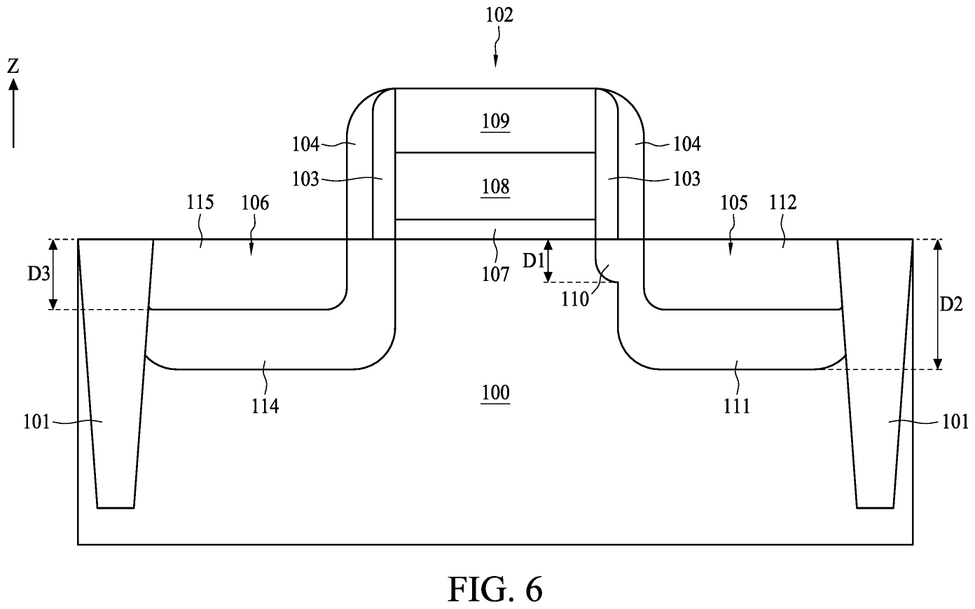

Alternatively, in another embodiment depicted, with reference to FIG. 6, the first doped region 105 and the second doped region 106 are asymmetrical. Specifically, the second doped region 106 includes only a medium-doped area 114 and a heavily-doped area 115. Part of the medium-doped area 114 of the second doped region 106 is below the other of the plurality of first spacers 103 and the other of the plurality of second spacers 104. A top surface of the medium-doped area 114 of the second doped region 106 contacts the bottom surfaces of the other of the plurality of first spacers 103 and the other of the plurality of second spacers 104. The heavily-doped area 115 of the second doped region 106 is enclosed by the medium-doped area 114 of the second doped region 106.

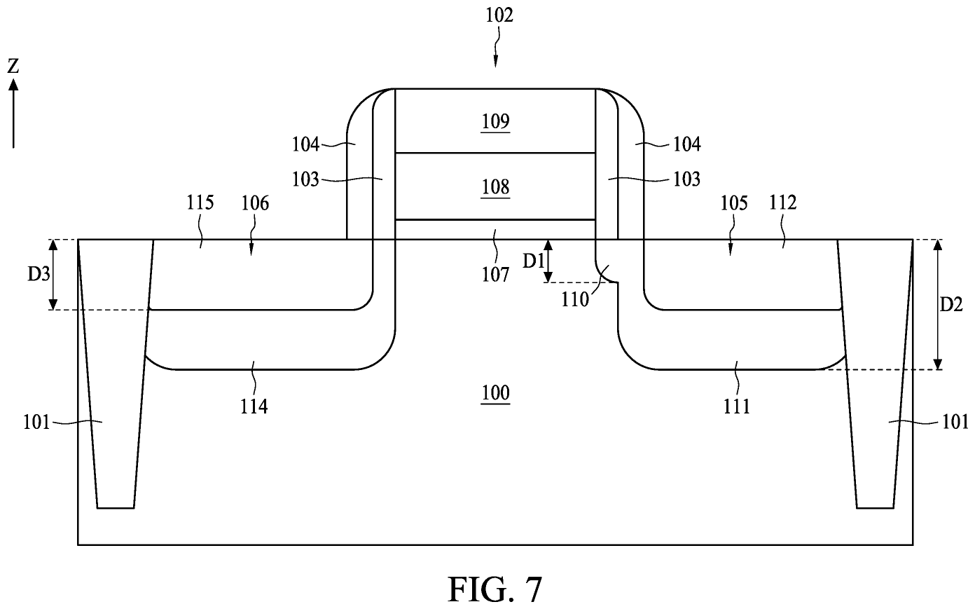

Alternatively, in another embodiment depicted, with reference to FIG. 7, the first doped region 105 and the second doped region 106 are asymmetrical. Specifically, the second doped region 106 includes only a medium-doped area 114 and a heavily-doped area 115. Part of the medium-doped area 114 of the second doped region 106 is below the other of the plurality of first spacers 103. A top surface of the medium-doped area 114 of the second doped region 106 contacts the bottom surface of the other of the plurality of first spacers 103. Part of the heavily-doped area 115 of the second doped region 106 is below the other of the plurality of second spacers 104. A top surface of the heavily-doped area 115 of the second doped region 106 contacts the bottom surface of the other of the plurality of second spacers 104. The heavily-doped area 115 of the second doped region 106 is enclosed by the medium-doped area 114 of the second doped region 106.

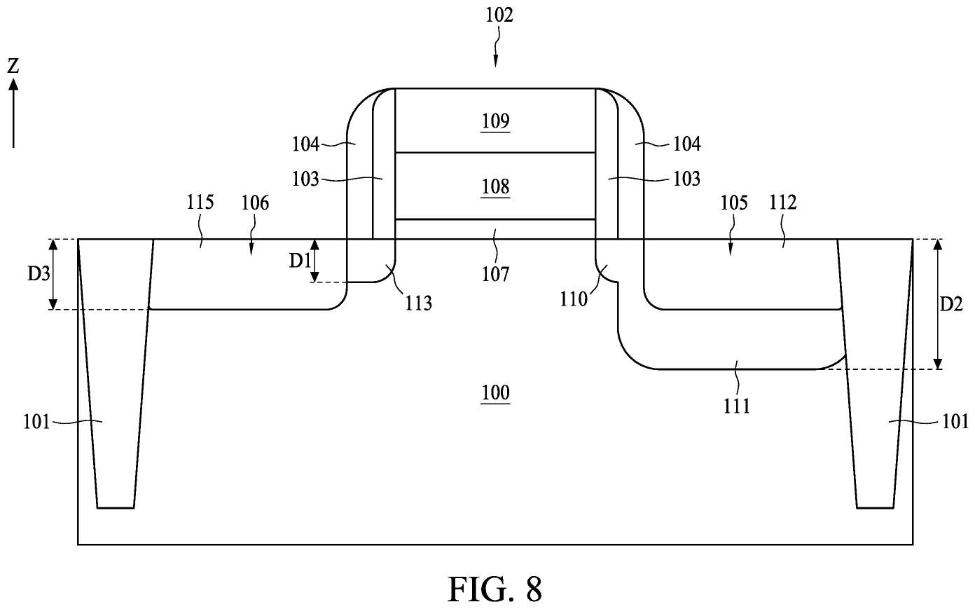

Alternatively, in another embodiment depicted, with reference to FIG. 8, the first doped region 105 and the second doped region 106 are asymmetrical. Specifically, the second doped region 106 includes only a lightly-doped area 113 and a heavily-doped area 115. Part of the lightly-doped area 113 of the second doped region 106 is below the other of the plurality of first spacers 103 and the other of the plurality of second spacers 104. A top surface of the lightly-doped area 113 of the second doped region 106 contacts the bottom surfaces of the other of the plurality of first spacers 103 and the other of the plurality of second spacers 104. The heavily-doped area 115 of the second doped region 106 abuts against the lightly-doped area 113 of the second doped region 106.

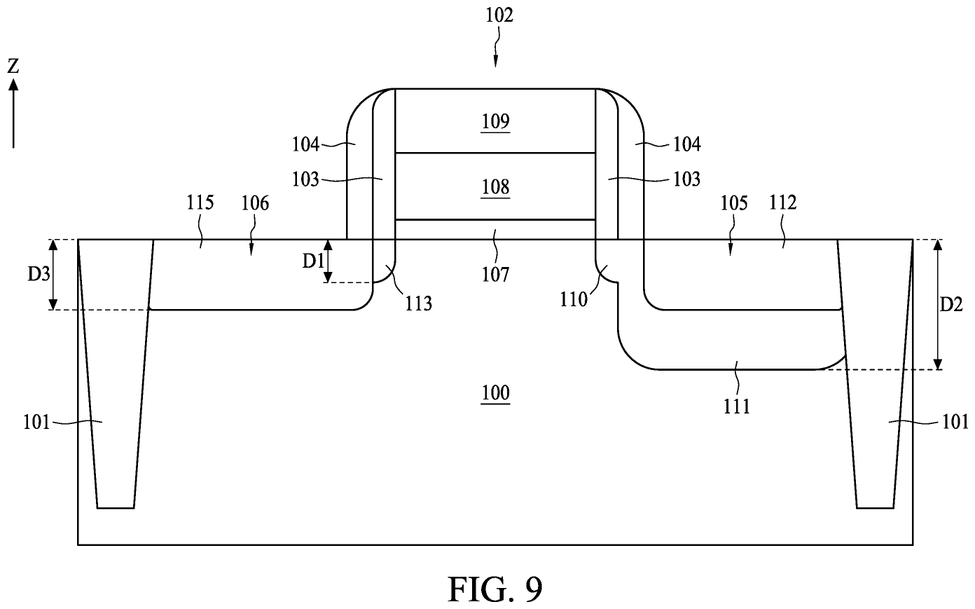

Alternatively, in another embodiment depicted, with reference to FIG. 9, the first doped region 105 and the second doped region 106 are asymmetrical. Specifically, the second doped region 106 includes only a lightly-doped area 113 and a heavily-doped area 115. Part of the lightly-doped area 113 of the second doped region 106 is below the other of the plurality of first spacers 103. A top surface of the lightly-doped area 113 of the second doped region 106 contacts the bottom surface of the other of the plurality of first spacers 103. Part of the heavily-doped area 115 of the second doped region 106 is below the other of the plurality of second spacers 104. A top surface of the heavily-doped area 115 of the second doped region 106 contacts the bottom surface of the other of the plurality of second spacers 104. The heavily-doped area 115 of the second doped region 106 abuts against the lightly-doped area 114 of the second doped region 106.

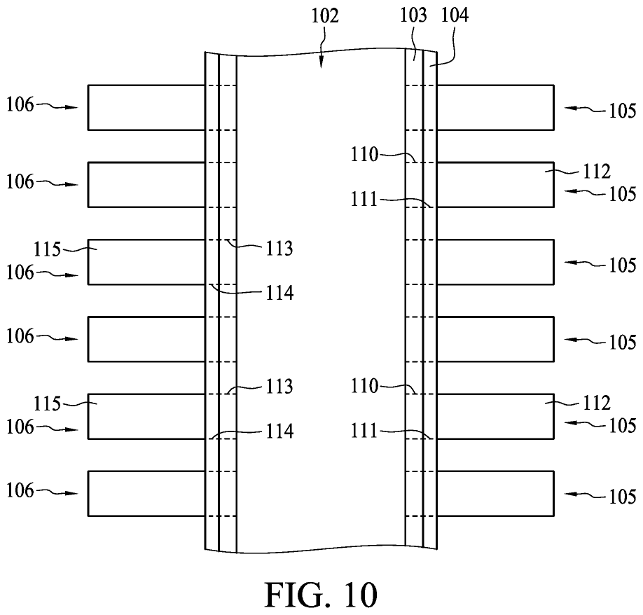

Alternatively, in another embodiment depicted, with reference to FIG. 10, the semiconductor device includes a plurality of first doped regions 105 and a plurality of second doped regions 106. The plurality of first doped regions 105 are formed in the substrate 100. The plurality of first doped regions 105 alternately abut against the edge of the control structure 102. Each of the plurality of first doped regions 105 includes a lightly-doped area 110, a medium-doped area 111, and a heavily-doped area 112.

With reference to FIG. 10, the lightly-doped areas 110 of the plurality of first doped regions 105 alternately abut against the one edge of the insulating layer 107 of the control structure 102. The lightly-doped areas 110 of the plurality of first doped regions 105 are below the one of the plurality of the first spacers 103, respectively. Top surfaces of the lightly-doped areas 110 of the plurality of first doped regions 105 respectively contact the bottom surface of the one of the plurality of first spacers 103.

With reference to FIG. 10, the medium-doped areas 111 of the plurality of first doped regions 105 correspondingly respectively abut against the lightly-doped areas 110 of the plurality of first doped regions 105. Parts of the medium-doped areas 111 of the plurality of first doped regions 105 are below the one of the plurality of second spacers 104, respectively. Top surfaces of the medium-doped areas 111 of the plurality of first doped regions 105 respectively contact the bottom surface of the one of the plurality of second spacers 104.

With reference to FIG. 10, the heavily-doped areas 112 of the plurality of first doped regions 105 are correspondingly respectively enclosed by the medium-doped areas 111 of the plurality of first doped regions 105. The heavily-doped areas 112 of the plurality of first doped regions 105 are correspondingly respectively opposite to the lightly-doped areas 110 of the plurality of first doped regions 105 with the medium-doped areas 111 of the plurality of first doped regions 105 correspondingly respectively interposed therebetween. The heavily-doped areas 112 of the plurality first doped regions 105 are not below the control structure 102, the one of the plurality of first spacers 103, or the one of the plurality of second spacers 104.

With reference to FIG. 10, the plurality of second doped regions 106 may be formed in the substrate 100 and may be correspondingly respectively symmetrical to the plurality of first doped region 105. The plurality of second doped regions 106 alternately abut against the other edge of the control structure 102.

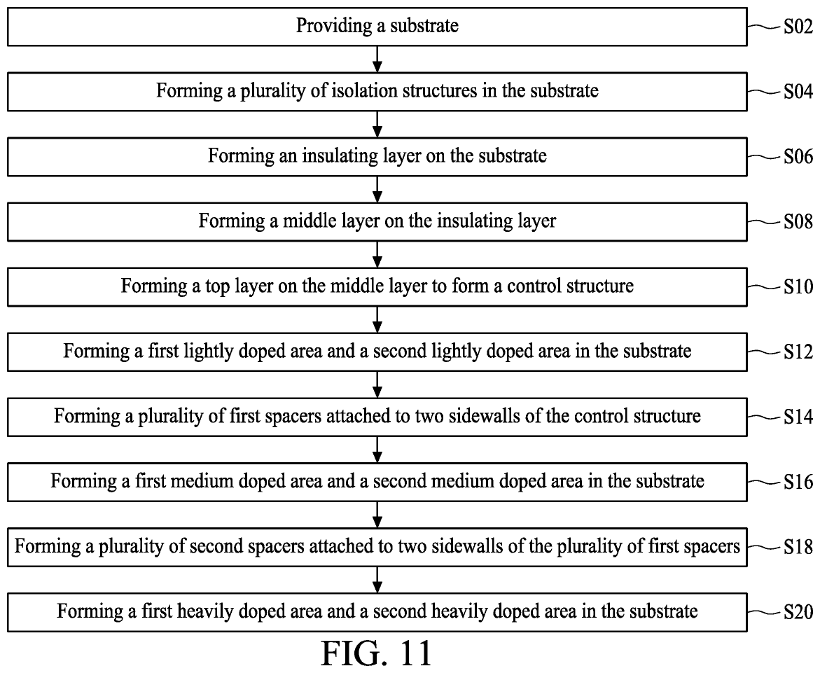

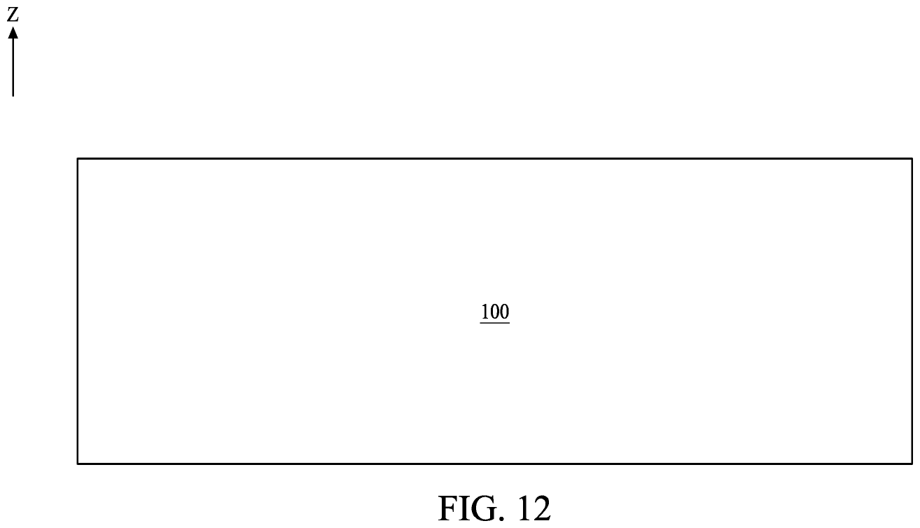

With reference to FIG. 11 and FIG. 12, at step S02, a substrate 100 is provided. The substrate 100 is formed of, for example, silicon, doped silicon, silicon germanium, silicon on insulator, silicon on sapphire, silicon germanium on insulator, silicon carbide, germanium, gallium arsenide, gallium phosphide, gallium arsenide phosphide, indium phosphide, indium gallium phosphide or any other IV-IV, III-V or II-VI semiconductor material. In the embodiment depicted, the substrate 100 is formed of doped silicon, which is doped with boron.

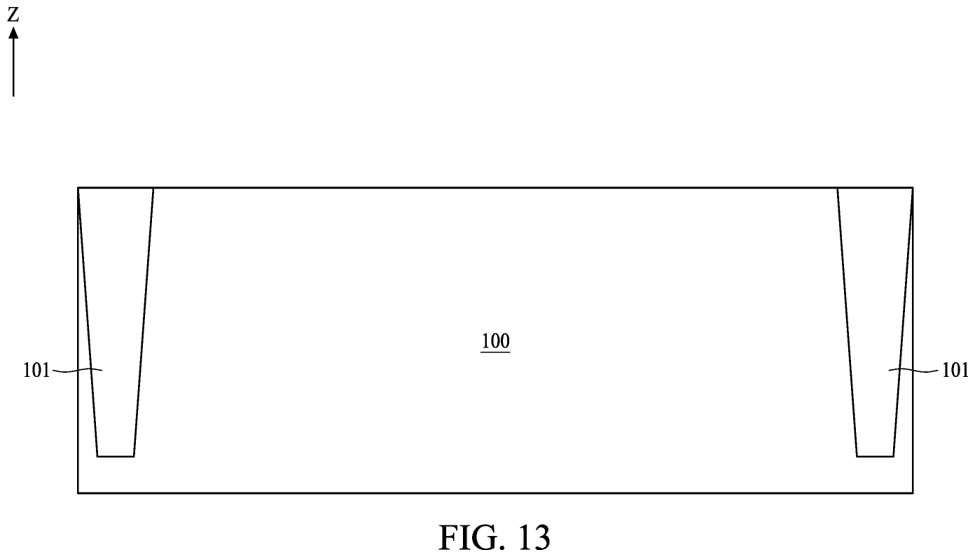

With reference to FIG. 11 and FIG. 13, at step S04, a plurality of isolation structures 101 are formed in the substrate 100. The plurality of isolation structures 101 are separated from each other and define an active region of the semiconductor device. The plurality of isolation structures 101 are formed of, for example, an insulating material such as silicon oxide, silicon nitride, silicon oxynitride, silicon nitride oxide, fluoride-doped silicate, or the like. In the embodiments depicted, the plurality of isolation structures 101 are formed of silicon oxide.

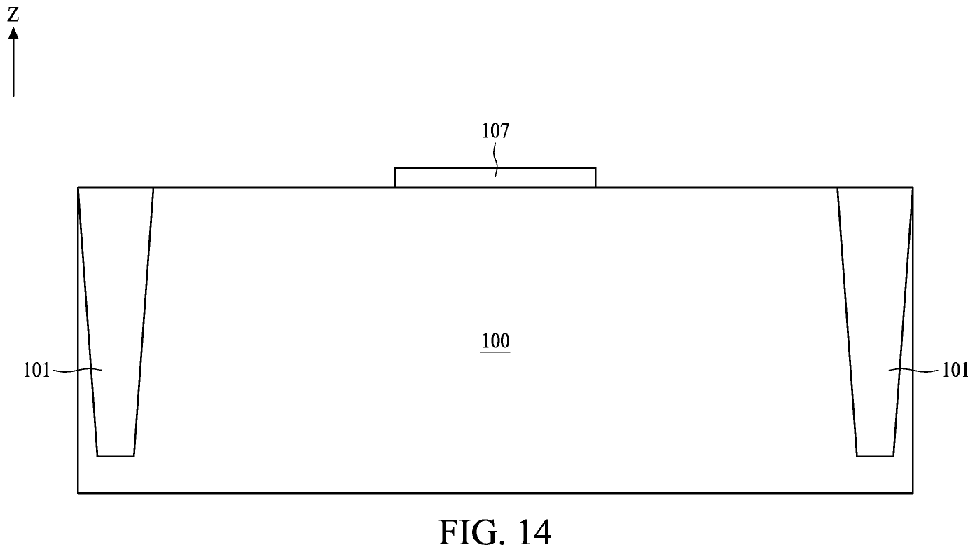

With reference to FIG. 11 and FIG. 14, at step S06, an insulating layer 107 is formed on the substrate 100. The insulating layer 107 is formed of, for example, silicon oxide, silicon oxynitride, silicon nitride oxide, silicon nitride, or the like. In the embodiment depicted, the insulating layer 107 is formed of silicon oxide.

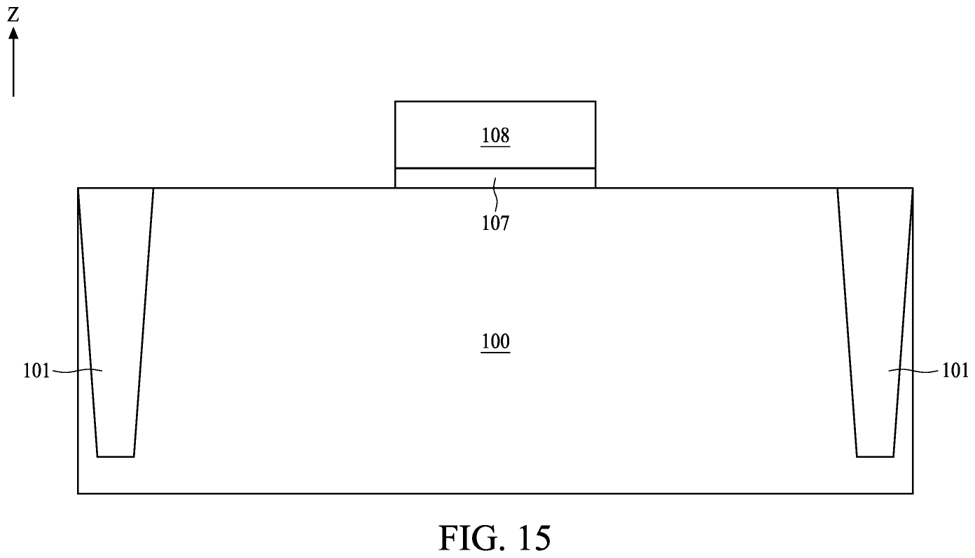

With reference to FIG. 11 and FIG. 15, at step S08, a middle layer 108 is formed on the insulating layer 107. The middle layer 108 is formed of, for example, polysilicon. In the embodiment depicted, the middle layer 108 is formed of polysilicon doped with phosphorus.

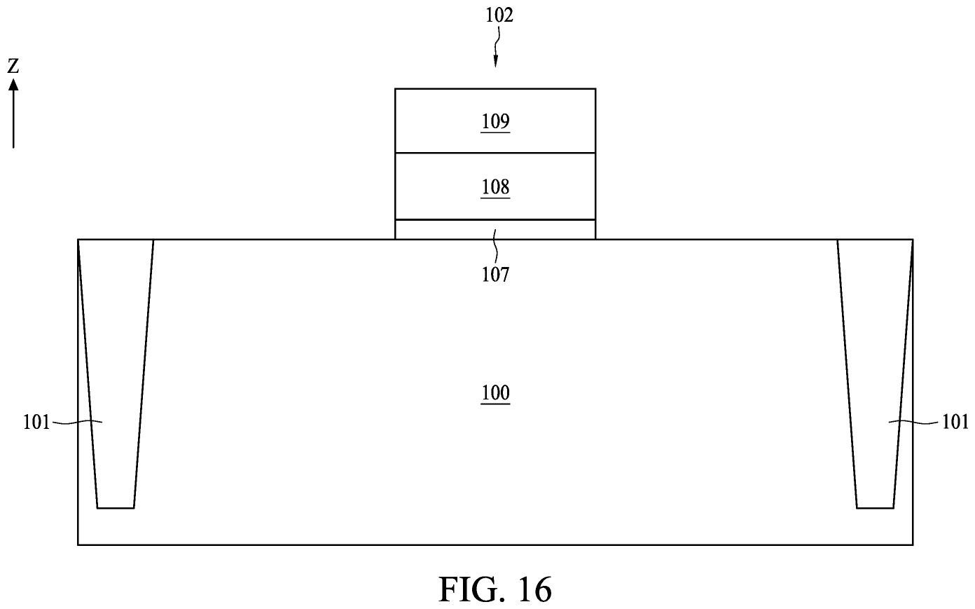

With reference to FIG. 11 and FIG. 16, at step S10, a top layer is formed on the middle layer 108. The top layer 109 is formed of, for example, a metal silicide such as nickel silicide, platinum silicide, titanium silicide, molybdenum silicide, cobalt silicide, tantalum silicide, tungsten silicide, or the like. In the embodiment depicted, the top layer 109 is formed of tungsten silicide. The insulating layer 107, the middle layer 108, and the top layer 109 together form a control structure 102. The control structure 102 has two sidewalls. The insulating layer 107 has two edges.

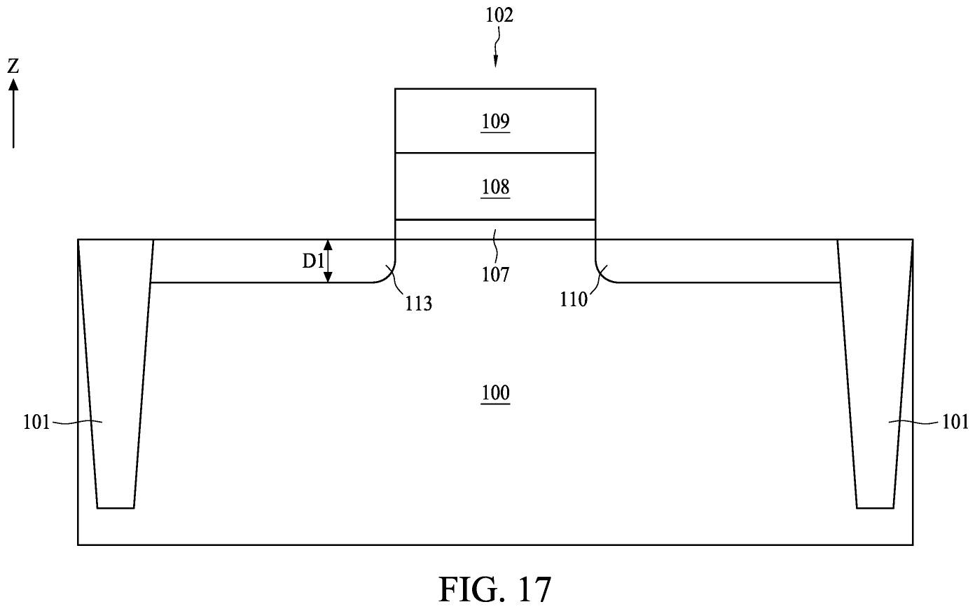

With reference to FIG. 11 and FIG. 17, at step S12, a first lightly-doped area 110 and a second lightly-doped area 113 are respectively formed in the substrate 100. The first lightly-doped area 110 and the second lightly-doped area 113 are separated from each other. The first lightly-doped area 110 abuts against one of the two edges of the insulating layer 107 and occupies a space between the one of the two edges of the insulating layer 107 and one of the plurality of isolation structures 101. The first lightly-doped area 110 has a depth D1 and a dopant concentration C1 ranging from about 1E14 atoms/cm³ to about 1E16 atoms/cm³. The second lightly-doped area 113 abuts against the other one of the two edges of the insulating layer 107 and occupies a space between the other one of the two edges of the insulating layer 107 and the other of the plurality of isolation structures 101. The second lightly-doped area 113 has a depth equal to the depth D1 of the first lightly-doped area 110 and has a dopant concentration equal to the dopant concentration C1 of the first lightly-doped area 110. An implantation process using the control structure 102 as a mask is performed to form the first lightly-doped area 110 and the second lightly-doped area 113. An implantation energy is about 0.1 keV to about 30 keV and an implantation concentration is about 1E12 atoms/cm² to about 1E14 atoms/cm². Due to the control structure 102 acting as the mask during the implantation process, no extra mask is needed for forming the first lightly-doped area 110 and the second lightly-doped area 113. Therefore, the complexity and cost of fabrication of the semiconductor device may be reduced.

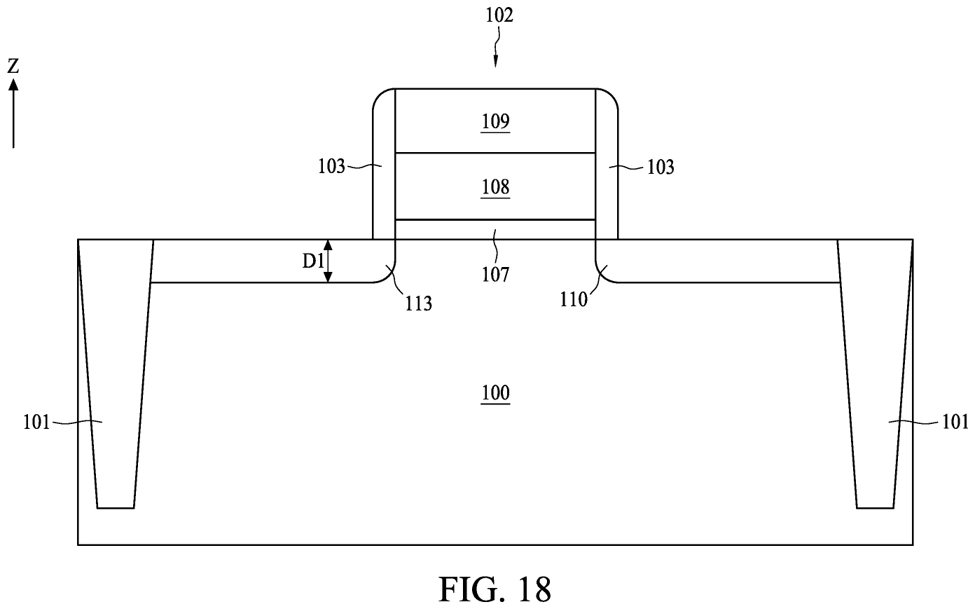

With reference to FIG. 11 and FIG. 18, at step S14, a plurality of first spacers 103 are formed above the substrate 100. The plurality of first spacers 103 are separated from each other and are respectively attached to the two sidewalls of the control structure 102. Bottom surfaces of the plurality of first spacers 103 respectively contact a top surface of the first lightly-doped area 110 and a top surface of the second lightly-doped area 113. The plurality of first spacers 103 are formed of, for example, silicon oxide, silicon nitride, polysilicon, or the like. In the embodiment depicted, the plurality of first spacers 103 are formed of silicon nitride. A deposition process and an etch process are performed to form the plurality of first spacers 103. The deposition process may be chemical vapor deposition or the like. The etch process may be an anisotropic dry etch process and is performed after the deposition process.

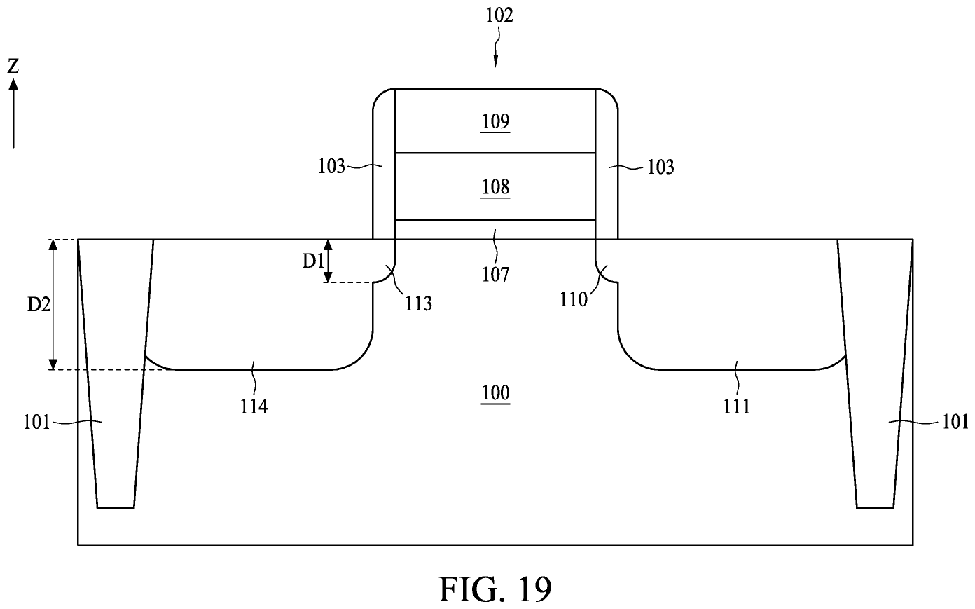

With reference to FIG. 11 and FIG. 19, at step S16, a first medium-doped area 111 and a second medium-doped area 114 are respectively formed in the substrate 100. The first medium-doped area 111 abuts against the first lightly-doped area 110. The first medium-doped area 111 occupies a space between one of the plurality of first spacers 103 and the one of the plurality of isolation structures 101. The first medium-doped area 111 has a depth D2 and has a dopant concentration C2 ranging from about 1E15 atoms/cm³ to about 1E17 atoms/cm³. The second medium-doped area 114 abuts against the second lightly-doped area 113. The second medium-doped area 114 occupies a space between the other of the plurality of first spacers 103 and the other of the plurality of isolation structures 101. The second medium-doped area 114 has a depth equal to the depth D2 of the first medium-doped area 111 and has a dopant concentration equal to the dopant concentration C2 of the first medium-doped area 111. An implantation process using the plurality of first spacers 103 as a mask is performed to form the first medium-doped area 111 and the second medium-doped area 114. An implantation energy is about 50 keV to about 200 keV and an implantation concentration is about 1E14 atoms/cm² to about 1E15 atoms/cm². Due to the plurality of first spacers 103 acting as the mask during the implantation process, no extra mask is needed for forming the first medium-doped area 111 and the second medium-doped area 114. Therefore, the complexity and cost of fabrication of the semiconductor device may be reduced.

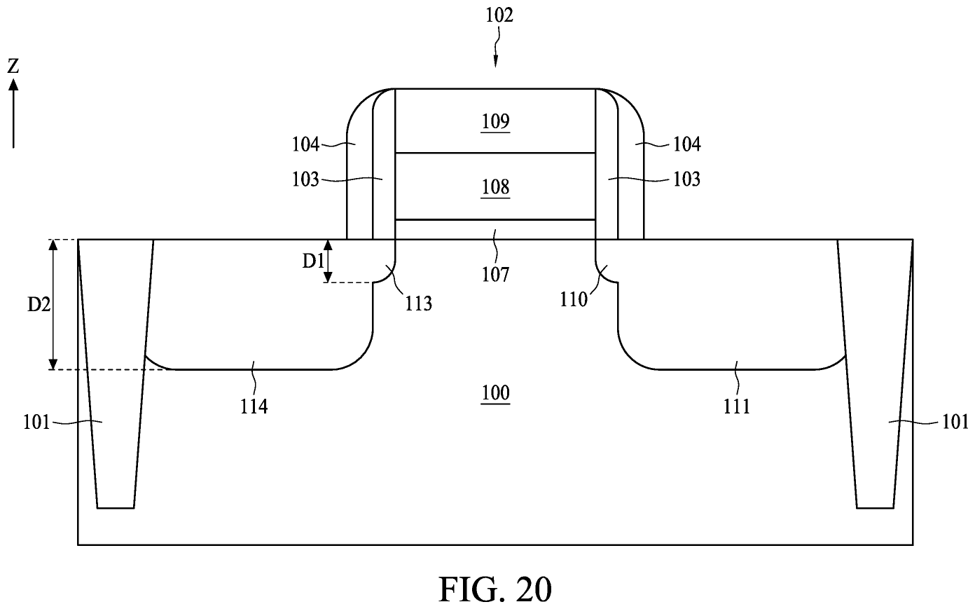

With reference to FIG. 11 and FIG. 20, at step S18, a plurality of second spacers 104 are formed above the substrate 100. The plurality of second spacers 104 are separated from each other and are respectively attached to sidewalls of the plurality of first spacers 103. Bottom surfaces of the plurality of second spacers 104 respectively contact a top surface of the first medium-doped area 111 and a top surface of the second medium-doped area 114. The plurality of second spacers 104 are formed of, for example, silicon oxide, silicon nitride, or the like. In the embodiment depicted, the plurality of second spacers 104 are formed of silicon oxide. A deposition process and an etch process are performed to form the plurality of second spacers 104. The deposition process may be chemical vapor deposition or the like. The etch process may be an anisotropic dry etch process and is performed after the deposition process.

With reference to FIG. 1 and FIG. 11, at step S20, a first heavily-doped area 112 and a second heavily-doped area 115 are formed in the substrate 100. The first heavily-doped area 112 is opposite to the first lightly-doped area 110 with the first medium-doped area 111 interposed therebetween. The first heavily-doped area 112 occupies a space between one of the plurality of second spacers 104 and the one of the plurality of isolation structures 101. The first heavily-doped area 112 has a depth D3 and has a dopant concentration C3 ranging from about 1E17 atoms/cm³ to about 1E19 atoms/cm³. The first lightly-doped area 110, the first medium-doped area 111, and the first heavily-doped area 112 together form a first doped region 105. The second heavily-doped area 115 is opposite to the second lightly-doped area 113 with the second medium-doped area 114 interposed therebetween. The second heavily-doped area 115 occupies a space between the other of the plurality of second spacers 104 and the other of the plurality of isolation structures 101. The second heavily-doped area 115 has a depth equal to the depth D3 of the first heavily-doped area 112 and has a dopant concentration equal to the dopant concentration C3 of the first heavily-doped area 112. The second lightly-doped area 113, the second medium-doped area 114, and the second heavily-doped area 115 together form a second doped region 106. An implantation process using the plurality of second spacers 104 as a mask is performed to form the first heavily-doped area 112 and the second heavily-doped area 115. An implantation energy is about 50 keV to about 150 keV and an implantation concentration is about 1E15 atoms/cm² to about 5E15 atoms/cm². Due to the plurality of second spacers 104 acting as the mask during the implantation process, no extra mask is needed for forming the first heavily-doped area 112 and the second heavily-doped area 115. Therefore, the complexity and cost of fabrication of the semiconductor device may be reduced.

Using the control structure 102, the plurality of first spacers 103, and the plurality of second spacers as masks, no extra mask is needed for forming the first doped region 105 and the second doped region 106. Hence, the complexity and cost of fabrication of the semiconductor device may be reduced. In addition, the design of the first doped region 105 and the second doped region 106 may mitigate the hot electron effect in the semiconductor device. As a result, a reliable semiconductor device may be provided.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

1. A semiconductor device, comprising:
a substrate;
a control structure positioned in the substrate;
a plurality of first spacers positioned on two sidewalls of the control structure;
a plurality of second spacers positioned on sidewalls of the plurality of first spacers; and
a first doped region positioned in the substrate;
wherein the first doped region comprises a lightly-doped area, a medium-doped area, and a heavily-doped area, the lightly-doped area of the first doped region abuts against one edge of the control structure, the medium-doped area of the first doped region abuts against the lightly-doped area of the first doped region, and the heavily-doped area of the first doped region is enclosed by the medium-doped area of the first doped region;
wherein the control structure disposed on the substrate extends in a direction, and a length of the lightly-doped area of the first doped region along the direction is greater than a length of the medium-doped area of the first doped region along the direction and a length of the heavily-doped area of the first doped region along the direction.

2. The semiconductor device of claim 1, further comprising a second doped region positioned in the substrate and symmetrical to the first doped region.

3. The semiconductor device of claim 1, further comprising a second doped region positioned in the substrate, wherein the second doped region comprises a heavily-doped area, and the heavily-doped area of the second doped region abuts against another edge of the control structure.

4. The semiconductor device of claim 1, further comprising a second doped region positioned in the substrate, wherein the second doped region comprises a lightly-doped area and a heavily-doped area, wherein the lightly-doped area of the second doped region abuts against another edge of the control structure, and the heavily-doped area of the second doped region abuts against the lightly-doped area of the second doped region.

5. The semiconductor device of claim 1, further comprising a second doped region positioned in the substrate, wherein the second doped region comprises a medium-doped area and a heavily-doped area, wherein the medium-doped area of the second doped region abuts against another edge of the control structure, and the heavily-doped area of the second doped region is enclosed by the medium-doped area of the second doped region.

6. The semiconductor device of claim 1, wherein a dopant concentration of the medium-doped area of the first doped region is greater than a dopant concentration of the lightly-doped area of the first doped region.

7. The semiconductor device of claim 1, wherein a dopant concentration of the heavily-doped area of the first doped region is greater than a dopant concentration of the lightly-doped area of the first doped region.

8. The semiconductor device of claim 1, wherein a dopant concentration of the heavily-doped area of the first doped region is greater than a dopant concentration of the medium-doped area of the first doped region.

9. (canceled)

10. (canceled)

11. The semiconductor device of claim 1, wherein a length of the medium-doped area of the first doped region along the direction is greater than a length of the heavily-doped area of the first doped region along the direction.

12. (canceled)

13. The semiconductor device of claim 1, further comprising a plurality of isolation structures formed in the substrate.

14. The semiconductor device of claim 13, wherein the plurality of isolation structures are formed of silicon oxide, silicon nitride, silicon oxynitride, silicon nitride oxide, or fluoride-doped silicate.

15. The semiconductor device of claim 1, wherein the control structure comprises an insulating layer, a medium layer, and a top layer, the insulating layer is positioned above the substrate, the medium layer is positioned above the insulating layer, and the top layer is positioned above the medium layer.

16. The semiconductor device of claim 15, wherein the insulating layer is formed of silicon oxide, silicon oxynitride, silicon nitride oxide, or silicon nitride.

17. The semiconductor device of claim 15, wherein the middle layer is formed of polysilicon.

18. The semiconductor device of claim 15, wherein the top layer is formed of metal silicide.

19. A semiconductor device, comprising:
a substrate;
a control structure positioned in the substrate;
a plurality of first spacers positioned on two sidewalls of the control structure;
a plurality of second spacers positioned on sidewalls of the plurality of first spacers; and
a plurality of first doped regions positioned in the substrate;
wherein each of the plurality of first doped regions comprises a lightly-doped area, a medium-doped area, and a heavily-doped area, the lightly-doped areas of the plurality of first doped regions alternately abut against one edge of the control structure, the medium-doped areas of the plurality of first doped regions correspondingly respectively abut against the lightly-doped areas of the plurality of first doped regions, and the heavily-doped areas of the plurality of first doped region are correspondingly respectively enclosed by the medium-doped areas of the plurality of first doped regions;
wherein the control structure disposed on the substrate extends in a direction, and a length of the lightly-doped area of each of the plurality of first doped regions along the direction is greater than a length of the medium-doped area of each of the plurality of first doped regions along the direction and a length of the heavily-doped area of each of the plurality of first doped regions along the direction.

20. A method for fabrication of a semiconductor device, comprising:
providing a substrate;
forming a control structure above the substrate, wherein the control structure disposed on the substrate extends in a direction;
forming a first lightly-doped area and a second lightly-doped area in the substrate, wherein the first lightly-doped area is separated from the second lightly-doped area;
forming a plurality of first spacers attached to two sidewalls of the control structure;
forming a first medium-doped area and a second medium-doped area in the substrate, wherein the first medium-doped area is separated from the second medium-doped area;
forming a plurality of second spacers attached to two sidewalls of the plurality of first spacers; and
forming a first heavily-doped area and a second heavily-doped area in the substrate, wherein the first heavily-doped area is separated from the second heavily-doped area;
wherein a length of the lightly-doped area of the first doped region along the direction is greater than a length of the medium-doped area of the first doped region along the direction and a length of the heavily-doped area of the first doped region along the direction.
